(19) United States
(12) Patent Application Publication
(10) Pub. No.: US 2010/0181623 A1
(43) Pub. Date: Jul. 22, 2010

(54) SEMICONDUCTOR DEVICE HAVING DUMMY BIT LINE STRUCTURE

(75) Inventors: Gyong-Sub IM, Suwon-si (KR); Seug-Gyu KIM, Hwaseong-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: Samsung Electronics Co., Ltd., Suwon-si (KR)

(21) Appl. No.: 12/641,457

(22) Filed: Dec. 18, 2009

(30) Foreign Application Priority Data
Dec. 19, 2008 (KR) 10-2008-0129844

(51) Int. Cl. H01L 27/088

(52) U.S. Cl. 257/368; 257/E27.06

(57) ABSTRACT

A semiconductor device includes a substrate having a cell area including a memory cell region and a dummy cell region, gate structures formed in the cell region, an insulating interlayer formed on the substrate to cover the gate structures, plugs formed through the insulating interlayer, bit lines contacting the plugs in the memory cell region, and dummy bit line structures contacting the plugs in the dummy cell region. The dummy bit line structure prevents a leakage current generated in a peripheral circuit area from flowing into a cell area.

### CROSS-REFERENCE TO RELATED APPLICATION

This application claims priority under 35 U.S.C. §119 to Korean patent Application No. 10-2008-0129844 filed on Dec. 19, 2008, the subject matter of which is hereby incorporated by reference.

### BACKGROUND

The inventive concept relates to semiconductor devices having dummy bit line structures and methods of manufacturing semiconductor devices including dummy bit line structures. More particularly, the inventive concept relates to semiconductor devices including dummy bit line structures that prevent leakage current from being applied to memory cells of the semiconductor device, and methods of manufacturing same.

As semiconductor devices have become more densely integrated, the size of the unit cells for the semiconductor devices have been considerably reduced. Hence, the width and separating intervals defined by isolation layers in contemporary semiconductor devices have been greatly reduced.

Considering the dynamic random access memory (DRAM) as one example of contemporary semiconductor devices, one notes that isolation layers may not be properly formed on a semiconductor substrate, or circuit elements disposed in a peripheral circuit area of the substrate may fail due to ever decreasing design rules. As a result of these failures, leakage current may flow into a memory cell area of the DRAM from surrounding peripheral circuit area(s). The inflow of leakage current causes, among other problems, a failure of the dynamic refresh functionality within the DRAM.

FIGS. 1 and 2 are pictures taken with an electron microscopic showing a conventional semiconductor memory device. FIG. 1 shows a layout of the conventional semiconductor memory device, and FIG. 2 shows a contact failure within the conventional semiconductor memory device.

As is common, the conventional semiconductor memory device shown in FIG. 1 includes a peripheral circuit area “A” and an adjacent cell area “B”. As the design rule of the conventional semiconductor memory device has been greatly reduced, an isolation layer between the peripheral circuit area A and the cell area B may not have a width sufficient to properly insulate the cell area B from leakage current (or other stray currents) arising in the peripheral circuit area A.

The very narrow (or thin) isolation layers demanded by current design rules may additionally cause so-called “pitting failures” between two metal contacts in the peripheral circuit area A that are adjacent to the cell area B, as shown in FIG. 2. Leakage current may flow along the portion of the contact having the pitting failure. This pitting failure may increase the leakage current in the semiconductor memory device, thereby causing refresh failures for cell transistors in the semiconductor memory device. That is, the leakage current generated in the peripheral circuit area A may flow into the cell area B, such that the threshold voltages of cell transistors may be reduced, thereby causing refresh failures.

### SUMMARY

Embodiments of the inventive concept provide a semiconductor device having a dummy bit line structure preventing a leakage current from flowing to memory cells of the semiconductor device. Embodiments of the inventive concept also provide methods of manufacturing semiconductor devices having this type of dummy bit line structures.

According to one aspect of certain embodiments, there is provided a semiconductor device including a substrate having a cell area including a memory cell region and a dummy cell region, gate structures formed in the cell region, an insulating interlayer formed on the substrate to cover the gate structures, plugs formed through the insulating interlayer, bit lines contacting the plugs in the memory cell region, and dummy bit line structures contacting the plugs in the dummy cell region.

In certain embodiments, isolation layers may be formed on the substrate. Source/drain regions may be provided between the gate structures in the memory cell region. Further, impurity regions may be formed between the isolation layers in the dummy cell region. One of the isolation layers between the memory cell region and the dummy cell region may have a width substantially larger than those of other isolation layers. The impurity regions may include P-type impurities.

In certain embodiments, a wiring electrically connected to the dummy bit line structures provides negative voltages to the dummy bit line structures. Here, the dummy bit line structures are electrically connected to the impurity regions.

In certain embodiments, dummy bit line spacers may be formed on sidewalls of the dummy bit line structures, respectively.

In certain embodiments, the dummy bit line structures may have constructions substantially the same as those of the bit lines. For example, each of the dummy bit line structures may include a dummy bit line and a dummy bit line mask. The dummy bit line may include doped polysilicon, metal and/or metal compound. The dummy bit line mask may include nitride or oxynitride.

In certain embodiments, a P-type well may be formed in the memory cell region whereas an N-type well may be formed in the dummy cell region.

In certain embodiments, a wiring electrically connected to the dummy bit line structures may be provided. Here, a negative voltage may be applied to the dummy bit line structures to prevent a leakage current generated in a peripheral circuit area of the substrate from flowing into the cell area of the substrate. Further, a positive voltage may be applied to at least one of the dummy bit line structures adjacent to the memory cell region.

According to another embodiment of the inventive concept, there is provided a method of manufacturing a semiconductor device. In the method of manufacturing the semiconductor device, isolation layers are formed on a substrate having a cell area including a memory cell region and a dummy cell region. Gate structures are formed in the cell region, and an insulating interlayer is formed on the substrate to cover the gate structures. Plugs are formed through the insulating interlayer. Bit lines are formed on the plugs and the insulating interlayer in the memory cell region. Dummy bit line structures are formed on the plugs and the insulating interlayer in the dummy cell region.

In certain embodiments, source/drain regions may be formed between adjacent gate structures in the memory cell region, and impurity regions may be formed between the isolation layers in the dummy cell region. Capacitors may be formed to be electrically connected to the source/drain regions. In some embodiments, the impurity regions may be formed by forming preliminary impurity regions between the isolation layers in the dummy cell region and by forming the impurity regions between the isolation layers in the dummy cell region by doping P-type impurities into the preliminary impurity regions. The source/drain regions and the preliminary impurity regions may be simultaneously formed. A P-type well may be formed in the memory cell region and an N-type well may be formed in the dummy cell region.

In certain embodiments, the bit lines and the dummy bit line structures may be simultaneously formed.

In certain embodiments, a wiring may be formed to be electrically connected to the dummy bit line structures for applying negative voltages to the dummy bit line structures.

According to certain embodiments of the inventive concept, a semiconductor device includes a dummy bit line structure for preventing a leakage current generated in a peripheral circuit area from flowing into a cell area. Thus, refresh failures of memory cells in the semiconductor device may be effectively prevented, and integration degree of the semiconductor device may be improved because the dummy bit line structure may have a construction substantially the same as or substantially similar to that of a bit line. Further, the dummy bit line structure of the semiconductor device may be obtained together with the bit line, so that manufacturing processes of the semiconductor device may be simplified.

### BRIEF DESCRIPTION OF THE DRAWINGS

Embodiments of the inventive concept may be understood in more detail from the following description taken in conjunction with the accompanying drawings, in which:

FIG. 1 is an electron microscopic picture showing a conventional semiconductor memory device;

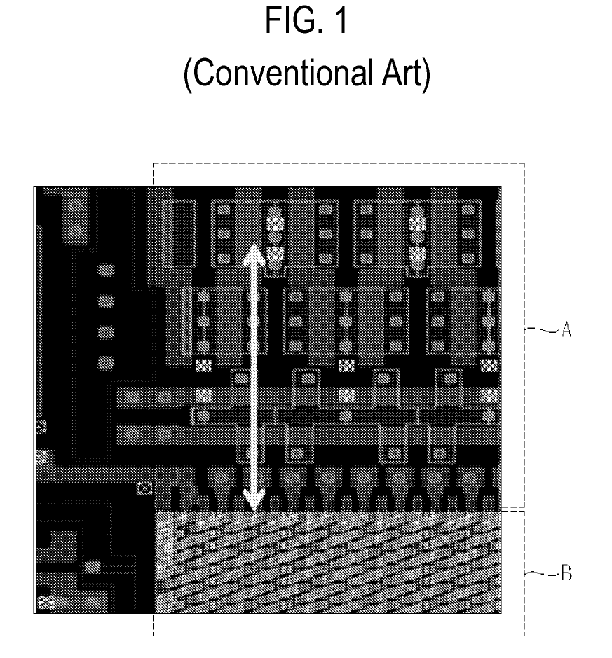

FIG. 2 is an electron microscopic picture showing a contact failure of the conventional semiconductor memory device;

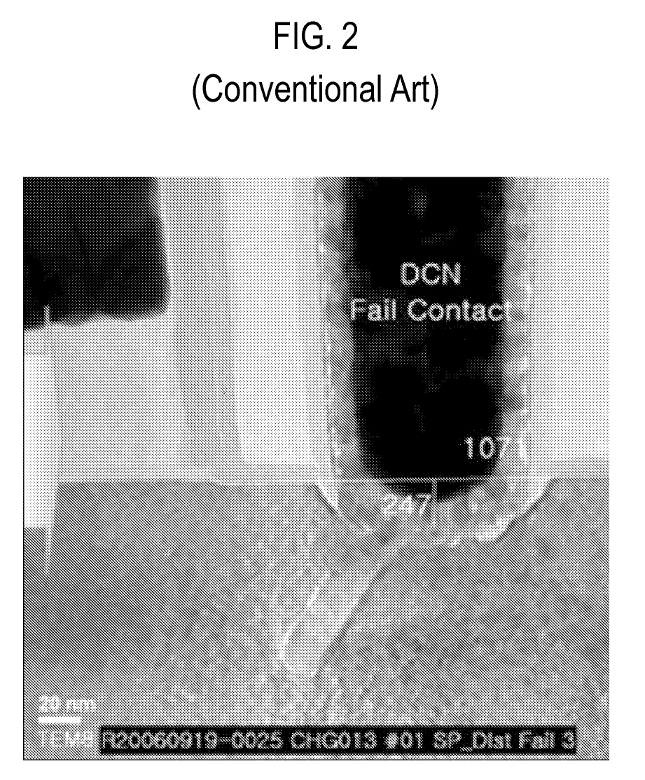

FIG. 3 is a plan view illustrating a semiconductor device having a dummy bit line structure in accordance with certain embodiments of the inventive concept;

FIG. 4 is a cross sectional view illustrating the semiconductor device taken along a line of VI-VII in FIG. 4;

FIG. 5 is a cross sectional view illustrating a semiconductor device having a dummy bit line structure in accordance with certain embodiments of the inventive concept;

FIG. 6 is a cross sectional view illustrating a semiconductor device having a dummy bit line structure in accordance with certain embodiments of the inventive concept;

FIGS. 7 to 9 are cross sectional views illustrating a method of manufacturing a semiconductor device having a dummy bit line structure in accordance with certain embodiments of the inventive concept;

FIGS. 10 to 12 are cross sectional views illustrating a method of manufacturing a semiconductor device having a dummy bit line structure in accordance with certain embodiments of the inventive concept;

FIGS. 13 and 14 are cross sectional views illustrating a method of manufacturing a semiconductor device having a dummy bit line structure in accordance with certain embodiments of the inventive concept;

FIGS. 15 to 17 are cross sectional views illustrating a method of manufacturing a semiconductor device having a dummy bit line structure in accordance with certain embodiments of the inventive concept; and

FIG. 18 is a general block diagram illustrating a memory system capable of incorporating a semiconductor device in accordance with embodiments of the inventive concept.

### DESCRIPTION OF EMBODIMENTS

Embodiments of the inventive concept will now be described in some additional detail with reference to the accompanying drawings. The inventive concept may, however, be embodied in many different forms and should not be construed as being limited to only the illustrated embodiments. In the drawings, the size and relative sizes of layers and regions may be exaggerated for clarity. Throughout the written description and drawings, like or similar reference numbers or labels are used to denote like or similar elements.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, third etc. may be used herein to describe various elements, components, regions, layers, patterns and/or sections, these elements, components, regions, layers, patterns and/or sections should not be limited by these terms. These terms are only used to distinguish one element, component, region, layer pattern or section from another region, layer, pattern or section. Thus, a first element, component, region, layer or section discussed below could be termed a second element, component, region, layer or section without departing from the teachings of embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional illustrations that are schematic illustrations of illustratively idealized embodiments (and intermediate structures) of the inventive concept. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

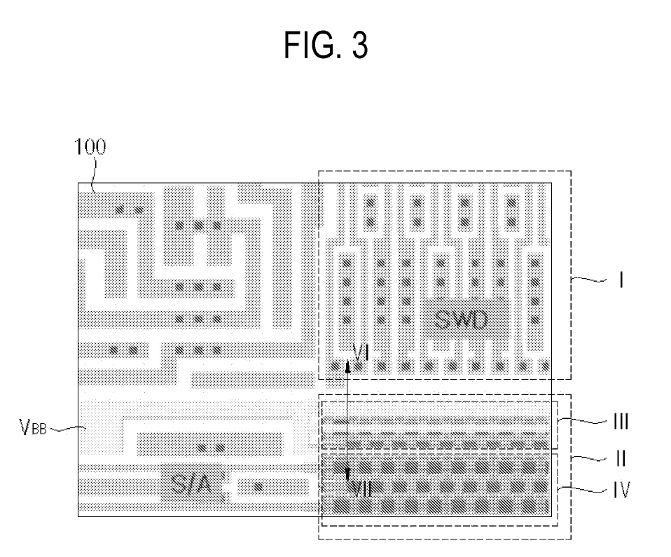

FIG. 3 is a plan view illustrating a semiconductor device having a dummy bit line structure in accordance with certain embodiments of the inventive concept.

Referring to FIG. 3, the semiconductor device comprises a substrate 100 divided into a peripheral circuit area “I” and a cell area “II”. The cell area II is further divided into a dummy cell region “III” and a memory cell region “IV”. Further, a sensing amplifier S/A may be provided adjacent to the cell area II, and power supply lines may be located adjacent to the peripheral circuit area I. A plurality of memory cells is formed in the cell area II, and conventionally understood circuit elements are disposed in the peripheral circuit area I.

In certain embodiments, the semiconductor device has a circuit layout in which the dummy bit line structure prevents a leakage current potentially generated within the peripheral circuit area I from flowing into the memory cells in the cell area II. When a negative voltage V_{BB} may be applied to the dummy bit line structure, the leakage current will not migrate from the peripheral circuit area I to the cell area II, thereby preventing the problems noted above in relation to conventional semiconductor memory devices.

In the illustrated embodiment of FIG. 3, the dummy cell region III is located between the memory cell region IV and a sub-word line driver (SWD) disposed in the peripheral circuit area I. The negative voltage V_{BB} may be applied to the dummy bit line structure so that the dummy bit line structure may serve as a terminal compensating a well bias within the semiconductor device. In certain embodiments of the inventive concept, a positive voltage may be applied to a bit line in the memory cell region IV, whereas the negative voltage V_{BB} may be applied to the dummy bit line structure in the dummy cell region III.

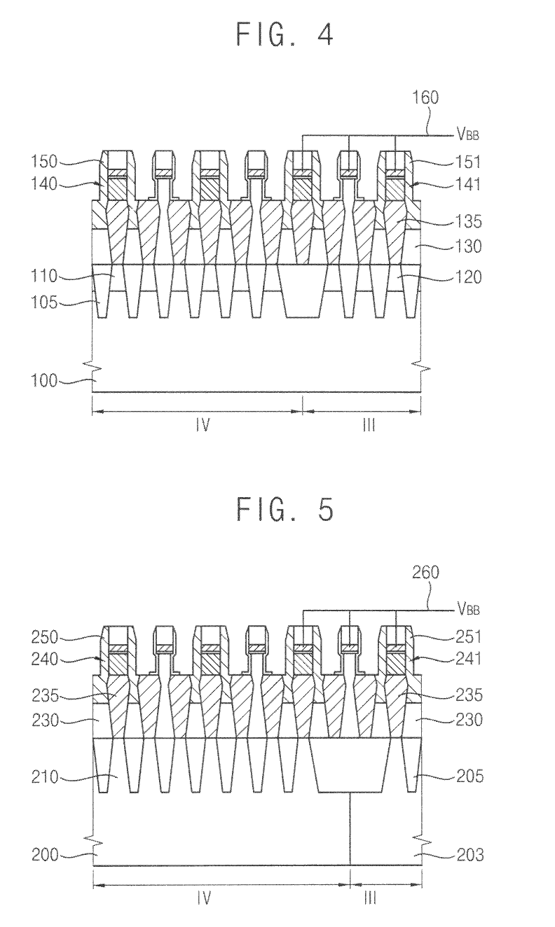

FIG. 4 is a cross sectional view further illustrating the semiconductor device of FIG. 3 and is taken along the line VI-VII shown in FIG. 3.

Referring to FIG. 4, the substrate 100 has the cell area II divided into the dummy cell region III and the memory cell region IV as described above. The substrate 100 may include a semiconductor substrate or a substrate having a semiconductor layer. For example, the substrate 100 may include a silicon (Si) substrate, a germanium (Ge) substrate, a silicon-on-insulator (SOI) substrate, a germanium-on-insulator (GOI) substrate, etc. The substrate 100 may include a P-type well formed in the memory cell region IV by doping P-type impurities into the portions of the substrate 100.

Isolation layers 105 are formed on the substrate 100 to isolate the memory cells from one another in the cell area II. The isolation layers 105 may include silicon oxide. For example, the isolation layers 105 may include udoped silicate glass (USG), spin on glass (SOG), boro-phosphor silicate glass (BPSG), tetraethyl ortho silicate (TEOS), Tonen Silazane (TOSZ), flowable oxide (FOX), high density plasma-chemical vapor deposition (HDP-CVD) oxide, etc.

In certain embodiments of the inventive concept, one of the isolation layers 105 may have a relatively large width between the memory cell region IV and the dummy cell region III. Thus, the isolation layer between the dummy cell region III and the memory cell region IV may ensure that the leakage current does not flow into the memory cell region IV.

The semiconductor device may include gate structures (not illustrated) buried in the substrate 100. Each of the gate structures may include a gate insulation layer and a gate electrode. Here, the gate insulation layer may be formed using silicon oxide and/or metal oxide, and the gate electrode may be formed using doped polysilicon, metal and/or metal compound.

Source/drain regions 110 are formed adjacent to the gate structures in the memory cell region IV. For example, one source/drain region may be located between adjacent gate structures. The source/drain regions 110 may be formed by implanting impurities into portions of the substrate 100 between adjacent gate structures.

Impurity regions 120 are positioned adjacent to the gate structures in the dummy cell region III. The impurity regions 120 may be formed by doping P-type impurities into portions of the substrate 100 between adjacent isolation layers 105 in the dummy cell region III. The impurity regions 120 may serve as passages through which the leakage current generated in the peripheral circuit area I flows when the well bias is applied to the dummy bit line structure.

An insulating interlayer 130 is formed on the substrate 100 having the isolation layers 105. The insulating interlayer 130 may include oxide such as USG, SOG, BPSG, TEOS, PE-TEOS, FOX, TOSZ, HDP-CVD oxide, etc. Plugs 135 are formed through the insulating interlayer 130. Each of the plugs 135 may include a conductive material, for example, metal, metal compound and/or doped polysilicon. The plugs 135 may make contact with the source/drain regions 110 and the impurity regions 120.

Bit lines 140 are provided on the plugs 135 in the memory cell region IV. Dummy bit line structures 141 are located on the plugs 135 in the dummy cell region III. In embodiments, the dummy bit line structures 141 may have constructions substantially the same as or substantially similar to those of the bit lines 140. For example, each of the bit lines 140 may include a bit line and a bit line mask. Additionally, each of the dummy bit line structures 141 may include a dummy bit line and a dummy bit line mask. The bit line and the dummy bit line may include conductive materials such as doped polysilicon, metal and/or metal compound. Further, the bit line mask and the dummy bit line mask may be formed using nitride or oxynitride.

Bit line spacers 150 are formed on sidewalls of the bit lines 140 and dummy bit line spacers 151 are positioned on sidewalls of the dummy bit line structures 141. The bit line spacers 150 and the dummy bit line spacers 151 may also include nitride or oxynitride. For example, the bit line spacers 150 and the dummy bit line spacers 151 may be formed using silicon nitride or silicon oxynitride.

In certain embodiments of the inventive concept, at least one of the bit lines 140 and dummy bit line structures 141 associated with odd lines are disposed on the plugs 135, whereas other ones of the bit lines 140 and dummy bit line structures 141 associated with even lines are disposed on the insulating interlayer 130.

A wiring 160 is electrically connected to the dummy bit line structures 141 in the dummy cell region III, such that the negative voltage V_{BB} may be applied to the dummy bit line structures 141 via the wiring 160. Thus, the well bias of the substrate 100 may be compensated for by application of the negative voltages V_{BB} to the dummy bit line structures 151.

In certain embodiments of the inventive concept, circuit elements including transistors may be provided in the peripheral circuit area I of the substrate 100 adjacent to the dummy cell region III. The transistors may include N-type metal oxide semiconductor (NMOS) transistors when the P-type well is formed in the memory cell region IV of the substrate 100. When the NMOS transistors are provided in the peripheral circuit area I adjacent to the dummy cell region III, pitting failures associated with plugs connected to the transistors may occur so that leakage current flows into the cell area I from the peripheral circuit area II. Such leakage current may vary with the well bias of the semiconductor device to reduce threshold voltage of cell transistors in the semiconductor device. For example, dynamic refresh failures may be generated along bit lines of the semiconductor when the pitting failures of the plugs are generated at the sub-word line driver (SWD) in the peripheral circuit area I. As a result, dynamic refresh failure of the cell transistors may be caused, thereby deteriorating the electrical performance characteristics of the semiconductor device.

As a conventional solution to this recurring set of problems, many semiconductor devices have been provided with an additional terminal in a peripheral circuit area to prevent leakage current from flowing into the cell area of the conventional semiconductor device. However, demands for greater integration density and reduced (i.e., less complicated) fabrication costs are at odds with the conventional remedy of providing an additional terminal for certain elements in the peripheral circuit area.

According to certain embodiments of the inventive concept, a semiconductor device compress dummy bit line structures in a dummy cell region adjacent to a memory cell region, wherein the dummy bit line structures may be fabricated with substantially the same structure as bit lines in the memory cell region. Therefore, a semiconductor device according to certain embodiments of the inventive concept may ensure improved electrical performance by preventing leakage current potentially generated in the peripheral circuit area from reaching the cell area. Further, such semiconductor devices have the potential for greater integration density at reduced overall fabrication cost and complexity, because the dummy bit line structures are disposed in a dummy cell region and the dummy bit line structures can be obtained together with the bit lines of the semiconductor device.

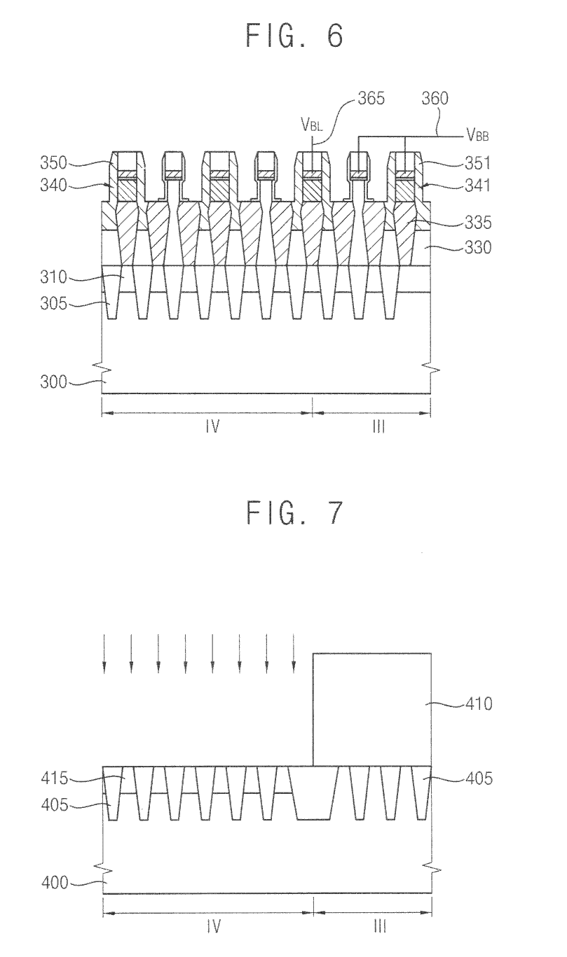

FIG. 5 is a cross sectional view further illustrating a semiconductor device having a dummy bit line structure in accordance with certain embodiments of the inventive concept.

Referring to FIG. 5, the semiconductor device comprises a substrate 200 having a cell area divided into a dummy cell region III and a memory cell region IV. The substrate 200 may include a semiconductor substrate or a substrate having a semiconductor layer. For example, the substrate 100 may include a silicon (Si) substrate, a germanium (Ge) substrate, a silicon-on-insulator (SOI) substrate, a germanium-on-insulator (GOI) substrate, etc. The substrate 200 may include a P-type well formed in the memory cell region IV by doping P-type impurities into the portions of the substrate 200. Further, the substrate 200 may include an N-type well 203 formed in the dummy cell region III by doping N-type impurities into the portions of the substrate 200.

Isolation layers 205 are formed on the substrate 200. The isolation layers 205 may include silicon oxide. One of the isolation layers 205 positioned between the memory cell region IV and the dummy cell region III may have a width considerably larger than other isolation layers 205. The semiconductor device may include gate structures (not illustrated) buried in the substrate 200. The gate structures may include gate insulation layers and gate electrodes, respectively. The gate insulation layers may include silicon oxide and/or metal oxide, and the gate electrodes may be include doped polysilicon, metal and/or metal compound.

Source/drain regions 210 are formed adjacent to the gate structures in the memory cell region IV. The source/drain regions 210 may be formed by implanting impurities into portions of the substrate 200 between adjacent gate structures. In certain embodiments, impurity regions (not illustrated) may be disposed in the N-type well 203 of the dummy cell region III. Here, the impurity regions may be formed by doping P-type impurities into portions of the substrate 200.

An insulating interlayer 230 is formed on the substrate 200 having the isolation layers 205. The insulating interlayer 230 may be formed form an oxide. Plugs 235 are disposed through the insulating interlayer 230. Each of the plugs 235 may include metal, metal compound and/or doped polysilicon. The plugs 235 make contact with the source/drain regions 210 and the N-type well 203. Further, the plugs 235 make contact with the impurity regions when the impurity regions are provided in the N-type well 203.

Bit lines 240 are disposed on the plugs 235 and the insulating interlayer 230 in the memory cell region IV. Further, dummy bit line structures 241 are provided on the plugs 235 and the insulating interlayer 230 in the dummy cell region III. The dummy bit line structures 241 in the illustrated embodiment have a structure substantially the same as the bit lines 240. For example, the bit lines 240 may include bit lines and bit line masks, and also the dummy bit line structures 241 may include dummy bits line and dummy bit line masks. The bit lines and the dummy bit lines may include doped polysilicon, metal and/or metal compound. Additionally, the bit line masks and the dummy bit line masks may include nitride or oxynitride.

Bit line spacers 250 are formed on sidewalls of the bit lines 240 and dummy bit line spacers 251 are positioned on sidewalls of the dummy bit line structures 241. The bit line spacers 250 and the dummy bit line spacers 251 may include nitride or oxynitride. Some of the bit lines 240 and the dummy bit line structures 241 in odd lines may positioned on the plugs 235 whereas others of the bit lines 240 and the dummy bit line structures 241 in even lines may be located on the insulating interlayer 230.

A wiring 260 is disposed over the dummy bit line structures 241 in order to be electrically connected to the dummy bit line structures 241 in the dummy cell region III. Thus, the negative voltage V_{BB} may be applied to the dummy bit line structures 241 via the wiring 260 to prevent a leakage current potentially generated in the peripheral circuit area from flowing into the cell area.

In certain embodiments of the inventive concept, the semiconductor device comprises the dummy bit line structures 241 in the dummy cell region III adjacent to the memory cell region IV, wherein the dummy bit line structures 241 have a structure substantially the same as (or substantially similar to) that of the bit lines 240 in the memory cell region IV. Therefore, a semiconductor device according to certain embodiments of the inventive concept may have improved electrical performance characteristics by preventing leakage current from flowing into the cell area. Additionally, such semiconductor devices may enable a very high degree of integration and cost effective fabrication, because the dummy bit line structures 241 may be obtained together with the bit lines 240.

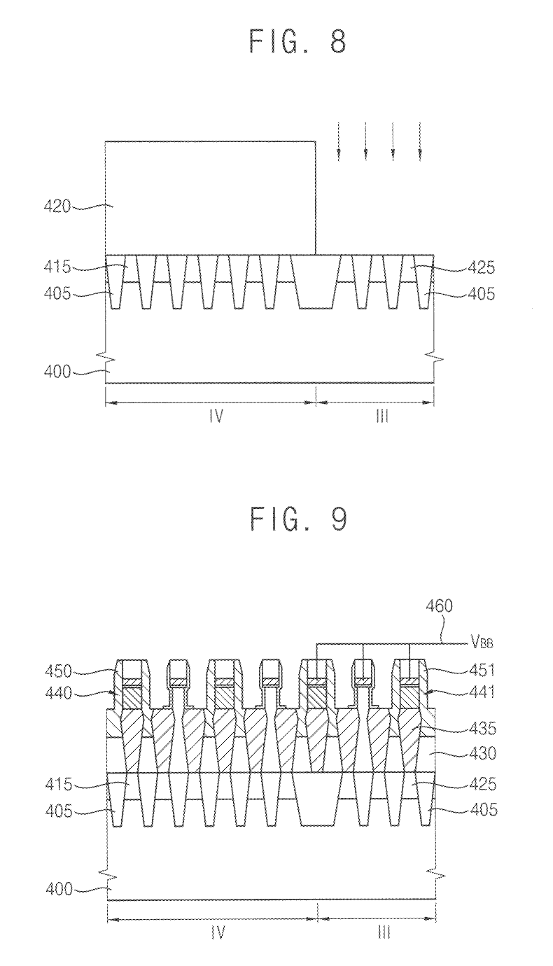

FIG. 6 is a cross sectional view illustrating a semiconductor device having a dummy bit line structure in accordance with embodiments.

Referring to FIG. 6, the semiconductor device comprising a substrate 300 having a cell area divided into a dummy cell region III and a memory cell region IV. The substrate 300 may include a semiconductor substrate or a substrate having a semiconductor layer. The substrate 300 may include a P-type well in the memory cell region IV. Isolation layers 305 are formed on the substrate 300. The isolation layers 205 may include silicon oxide. In embodiments, each of the isolation layers 305 may have a substantially the same width. Here, an additional P-type well may be provided in the dummy cell region III.

The semiconductor device may include gate structures (not illustrated) buried in the substrate 300. The gate structures may include gate insulation layers and gate electrodes, respectively. The gate insulation layers may include silicon oxide and/or metal oxide, and the gate electrodes may be include doped polysilicon, metal and/or metal compound. Source/drain regions 310 are formed adjacent to the gate structures in the memory cell region IV. Impurity regions (not illustrated) are disposed in the dummy cell region III. The impurity regions may be formed by doping N-type impurities into portions of the substrate 300 when the additional P-type well is disposed in the dummy cell region III.

An insulating interlayer 330 is formed on the substrate 300 having the isolation layers 305. Plugs 335 are disposed through the insulating interlayer 330. The plugs 335 may include metal, metal compound and/or doped polysilicon. The plugs 335 make contact with the source/drain regions 310 and the impurity regions. Bit lines 340 are disposed on the plugs 335 and the insulating interlayer 330 in the memory cell region IV. Dummy bit line structures 341 are disposed on the plugs 335 and the insulating interlayer 330 in the dummy cell region III. The dummy bit line structures 341 may have a structure substantially the same as (or substantially similar to) that of the bit lines 340. Bit line spacers 350 are formed on sidewalls of the bit lines 340 and dummy bit line spacers 351 are positioned on sidewalls of the dummy bit line structures 341. The bit line spacers 350 and the dummy bit line spacers 351 may include nitride or oxynitride. A wiring 360 is disposed over the dummy bit line structures 341 to be electrically connected to the dummy bit line structures 341 in the dummy cell region III. The negative voltage V_{BB} may be applied to the dummy bit line structures 341 via the wiring 360 to prevent leakage current potentially generated in the peripheral circuit area from flowing into the cell area. Meanwhile, positive voltages may be applied to the cell transistors of the semiconductor device. Further, a positive voltage may be applied to one of the dummy bit line structures 341 adjacent to the memory cell region IV. Thus, performance of the dummy bit line structure proximate the memory cell region IV may be improved by applying the positive voltage while more effectively preventing a leakage current from flowing into the cell area.

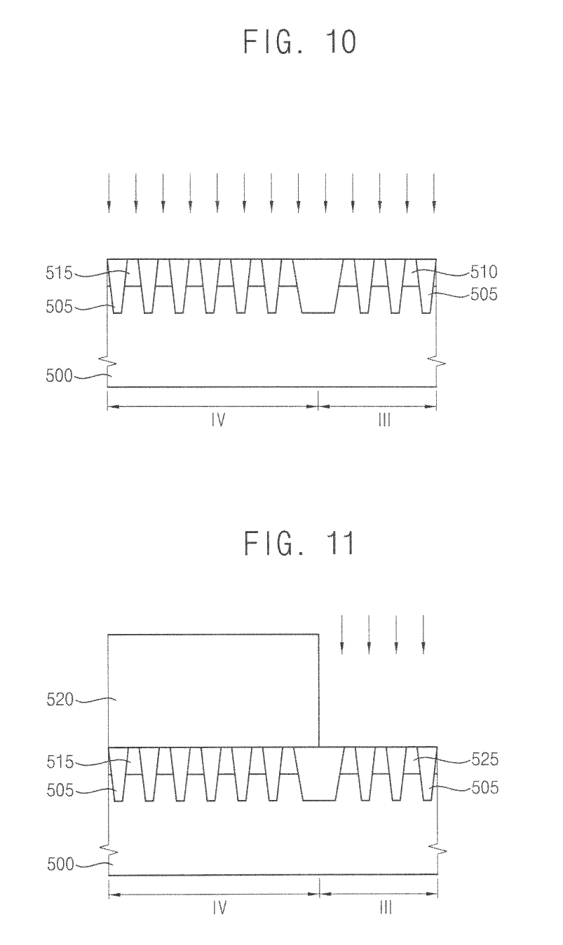

FIGS. 7, 8 and 9 are cross sectional views illustrating a method of manufacture for a semiconductor device having a dummy bit line structure in accordance with certain embodiments of the inventive concept.

Referring to FIG. 7, a semiconductor device is fabricated on a substrate 400 having a memory cell region IV and a dummy cell region III in a cell area. The substrate 400 may further include a peripheral circuit area (not illustrated). The substrate 400 may be formed from a semiconductor substrate, a substrate having a semiconductor layer, etc.

A pad oxide layer (not illustrated) is formed on the substrate 400. The pad oxide layer may be formed using silicon oxide by a thermal oxidation process or a CVD process. The pad oxide layer may have a thickness of about 50 Å to about 150 Å based on an upper surface of the substrate 400.

A first hard mask layer (not illustrated) is then formed on the pad oxide layer. The first hard mask layer may be formed using a material having an etching selectivity relative to the pad oxide layer and the substrate 400. For example, the first hard mask layer may include nitride such as silicon nitride or oxynitride like silicon oxynitride. Further, the first hard mask layer may be formed using such conventionally understood processes as chemical vapor disposition (CVD), plasma enhanced chemical vapor deposition (PECVD), atomic layer deposition (ALD), etc.

The first hard mask layer and the pad oxide layer are partially etched to form a pad oxide layer pattern and a first hard mask on the substrate 400. The first hard mask and the pad oxide layer pattern may be obtained, for example, by use of conventionally understood photolithography process(es).

Using the first hard mask and the pad oxide layer pattern as etching masks, the substrate 400 is partially etched to form a plurality of trenches (not illustrated) at an upper portion of the substrate 400. In certain embodiments of the inventive concept, one of the trenches positioned between the memory cell region IV and the dummy cell region III may have a greater width than the other trenches. The pad oxide layer pattern and the first hard mask may be removed from the substrate 400 after forming the trenches.

An insulation layer (not illustrated) is formed on the substrate 400 to fill up the trenches. The insulation layer may be formed using oxide. For example, the insulation layer may include USG, SOG, BPSG, PSG, TEOS, FOX, TOSZ, HDP-CVD oxide, etc. Further, the insulation layer may be formed on the substrate 400 by a CVD process, a PECVD process, a spin coating process, an ALD process, an HDP-CVD process, etc.

The insulation layer is removed until the substrate 400 is exposed, so that isolation layers 405 are formed in the trenches, respectively. The isolation layers 405 may be obtained by partially removing the insulation layer using a conventionally understood chemical mechanical polishing (CMP) process(es) and/or etch-back process(es). That is, the isolation layers 405 may be formed by an isolation process such as a shallow trench isolation (STI) process. Some of the isolation layers 405 in the memory cell region IV may define active regions of the substrate 400 where memory cells of the semiconductor device are positioned. In certain embodiments, one of the isolation layers 405 located between the memory cell region IV and the dummy cell region III may have a width greater than those of other isolation layers 405 because one of the trenches between the dummy cell region III and the memory cell region IV has a greater width, as described above.

In certain embodiments, a P-type well may be formed in the memory cell region IV the substrate 400 by doping P-type impurities into the substrate 400 after forming the isolation layers 405. Alternatively, the P-type well may be formed in the memory cell region IV before forming the isolation layers 405. Further, an N-type well may be formed in the dummy cell region III of the substrate 400 by implanting N-type impurities into the substrate 400 after forming the isolation layers 405 or before forming the isolation layers 405.

In certain embodiments, liner layers may be formed on sidewalls of the trenches before forming the isolation layers 405 filling the trenches. The line layers may be formed using nitride, for example, silicon nitride.

Second hard masks (not illustrated) are formed on the substrate 400 having the isolation layers 405. The second hard masks may expose the active regions defined by the isolation layers 405. The second hard masks may be formed using oxide, nitride and/or oxynitride. In some embodiments, each of the second hard masks may have a multi layer structure. For example, each second hard mask may have an oxide layer, an organic layer and a nitride layer. The oxide layer may include silicon oxide obtained by a CVD process, and the organic layer may include amorphous carbon layer. The oxide layer may have a thickness of about 2,000 Å to about 3,000 Å, and the organic layer may also have a thickness of about 2,000 Å to about 3,000 Å. Additionally, the nitride layer may include silicon nitride and may have a thickness of about 500 Å. The nitride layer may serve as an anti-reflective layer.

The exposed portions of the active regions are partially etched using the second hard masks as etching masks, such that a plurality of recesses (not illustrated) are provided at the active regions. The recesses may be obtained by an anisotropic etching process. When the P-type well is provided in the memory cell region IV of the substrate 400, the recesses may be located in the P-type well.

A gate conductive layer (not illustrated) and a gate mask layer (not illustrated) are formed on the substrate 400 having the recesses. Here, the gate conductive layer may be formed on the substrate 400 to fill up the recesses. The gate conductive layer may be formed using polysilicon, metal and/or metal compound. For example, the gate conductive layer may include polysilicon doped with impurities, tungsten (W), tungsten nitride (WNx), tungsten silicide (WSix), titanium (Ti), titanium nitride (TiNx), titanium silicide (TiSix), aluminum (Al), aluminum nitride (AlNx), nickel silicide (NiSix), zirconium silicide (ZrSix), tantalum (Ta), tantalum nitride (TaNx), etc. These materials may be used alone or in combination. The gate mask layer may be formed using nitride or oxynitride. For example, the gate mask layer may include silicon nitride or silicon oxynitride.

After the gate mask layer is etched to form gate masks (not illustrated) on the gate conductive layer, the gate conductive layer is patterned using the gate masks as etching masks. Thus, a plurality of gate structures (not illustrated) is formed on the active region of the substrate 400. Each of the gate structures includes a gate electrode and the gate mask. In certain embodiments, the gate electrodes may be buried in the substrate 400 because the gate conductive layer fills up the recesses.

A first mask 410 is formed on the substrate 400 to cover the dummy cell region III, so that the first mask 410 exposes the memory cell region IV of the substrate 400. The first mask 410 may be formed using an organic material, for example, photoresist.

With the first mask 410 as an implantation mask, impurities are doped into portions of the memory cell region IV adjacent to the gate structures. Hence, source/drain regions 415 are formed at the active regions between adjacent gate structures. The first mask 410 may be removed from the substrate 400 by an ashing process and/or a stripping process.

Referring to FIG. 8, a second mask 420 is formed on the substrate 400 to expose the dummy cell region III. Namely, the memory cell region IV is covered with the second mask 420. The second mask 420 may be formed using an organic material such as photoresist.

Using the second mask 420 as an implantation mask, impurities are doped into portions of the dummy cell region III between the isolation layers 405, so that impurity regions 425 are formed in the dummy cell region III. The impurity regions 425 may include P-type impurities, for example, boron (B), boron fluoride (BF₂), etc.

In some embodiments, the impurity region 425 may be formed in the dummy cell region III before forming the source/drain regions 415 in the memory cell region IV.

Referring to FIG. 9, an insulating interlayer 430 is formed on the substrate 400 to cover the gate structures. The insulating interlayer 430 covers the memory cell region IV and the dummy cell region III. The insulating interlayer 430 may be formed using oxide, for example, USG, SOG, BPSG, PSG, TEOS, PE-TEOS, FOX, TOSZ, HDP-CVD oxide, etc. Additionally, the insulating interlayer 430 may be formed by a CVD process, a PECVD process, a spin coating process, an ALD process, an HDP-CVD process, etc.

The insulating interlayer 430 is partially etched to form first contact holes (not illustrated) that expose the source/drain regions 415 in the memory cell region IV. Further, second contact holes (not illustrated) are formed through the insulating interlayer 430 in the dummy cell region III. The second contact holes expose the impurity regions 425 in the dummy cell region III. The first and the second contact holes may be formed by an anisotropic etching process using a third mask (not illustrated) provided on the insulating interlayer 430.

A conductive layer (not illustrated) is formed on the insulating interlayer 430 to fill up the first and the second contact holes, and then the conductive layer is removed until the insulating interlayer 430 is exposed. Thus, plugs 435 filling the first and the second contact holes are formed on the source/drain regions 415 and the impurity regions 425. The conductive layer may be formed using metal, doped polysilicon and/or metal compound. For example, the conductive layer may include polysilicon doped with impurities, tungsten, tungsten nitride, titanium, titanium nitride, aluminum, aluminum nitride, tantalum, tantalum nitride, etc. These materials may be used alone or in combination. Further, the plugs 435 may be finished by use of a CMP process and/or an etch-back process.

Bit lines 440 and dummy bit line structures 441 are formed on the plugs 435. The bit lines 440 and the dummy bit line structures 441 may be formed by patterning an additional conductive layer (not illustrated) formed on the plugs 435 and the insulating interlayer 430. Each of the bit lines 440 and the dummy bit line structures 441 may be formed using metal and/or metal compound. For example, the bit lines 440 may include tungsten, titanium, tantalum, platinum, aluminum, tungsten nitride, titanium nitride, aluminum nitride, tantalum nitride, etc. These materials may be used alone or in combination.

In certain embodiments, each of the bit lines 440 and the dummy bit line structures 441 may have a multi layer structure including at least one metal layer and at least one metal nitride layer.

Bit line spacers 450 and dummy bit line spacers 451 are formed on sidewalls of the bit lines 440 and the dummy bit line structures 441, respectively. The bit line spacers 450 and the dummy bit line spacers 451 may be formed using nitride or oxynitride. For example, the bit line spacers 450 and the dummy bit line spacers 451 may include silicon nitride or silicon oxynitride. In certain embodiments, a nitride layer or an oxynitride layer may be formed on the insulating interlayer 430 to cover the bit lines 440 and the dummy bit line structures 441, and then the nitride layer or the oxynitride layer may be anisotropically etched to form the bit line spacers 450 and the dummy bit line spacers 451 on the sidewalls of the bit lines 440 and the dummy bit line structures 441.

After an additional insulating interlayer (not illustrated) is formed on the insulating interlayer 430 to cover the bit lines 440 and the dummy bit line structures 441, capacitors (not illustrated) are provided on the additional insulating interlayer. The capacitors may be electrically connected to the source/drain regions 415 in the memory cell region IV.

The dummy bit line structures 441 are electrically connected to a wiring 460 so that the negative voltages V_{BB} may be applied to the dummy bit line structures 441 to prevent leakage current potentially generated in the peripheral area from flowing into the memory cell region IV. Thus, cell transistors in the memory cell region IV are able to maintain desired threshold voltages thereby preventing refresh failures. As a result, the semiconductor devices including the dummy bit line structures 441 may exhibit improved electrical performance.

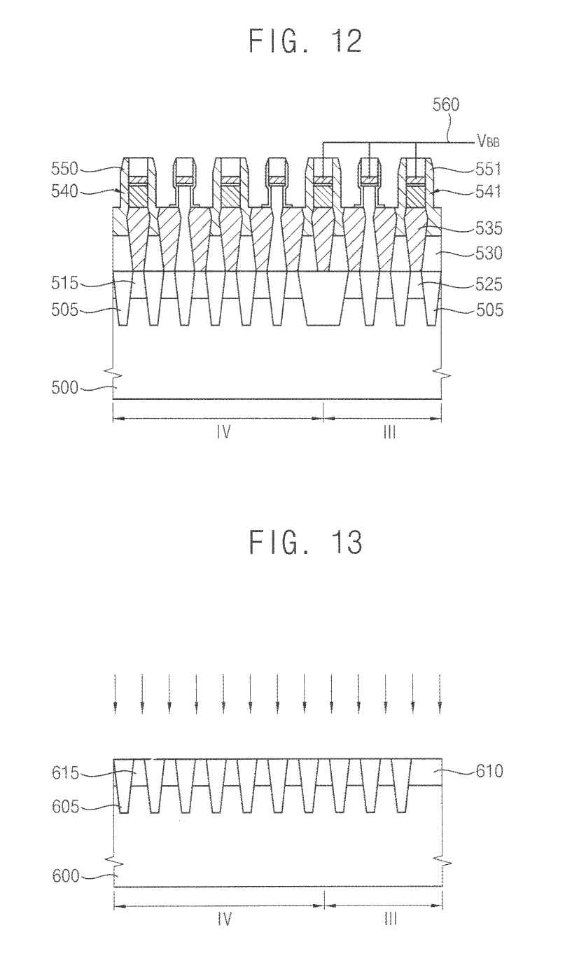

FIGS. 10, 11 and 12 are cross sectional views further illustrating a method of manufacturing a semiconductor device having a dummy bit line structure in accordance with certain embodiments of the inventive concept.

Referring to FIG. 10, a semiconductor device may be formed on a substrate 500 including a cell area and a peripheral circuit area. The cell area is divided into a memory cell region IV and a dummy cell region III. The substrate 500 may be formed from a semiconductor substrate, a substrate having a semiconductor layer, etc.

A pad oxide layer (not illustrated) is formed on the substrate 500. The pad oxide layer may have a relatively thin thickness of about 50 Å to 150 Å, as measured from an upper face of the substrate 500. A first hard mask layer (not illustrated) is formed on the pad oxide layer. The first hard mask layer may be formed using a material having an etching selectivity with respect to the pad oxide layer and the substrate 400. For example, the first hard mask layer may be formed using silicon nitride, silicon oxynitride, etc. The first hard mask layer may be formed by a CVD process, a PECVD process, an ALD process, etc.

The first hard mask layer and the pad oxide layer are etched to form a pad oxide layer pattern and a first hard mask on the substrate 500. The substrate 500 is partially etched using the first hard mask and the pad oxide layer pattern as etching masks so that trenches (not illustrated) are formed at an upper portion of the substrate 500. One trench located between the memory cell region IV and the dummy cell region III may have a greater width than the other trenches.

An insulation layer (not illustrated) filling the trenches is formed on the substrate 500. The insulation layer may be formed using oxide, for example, USG, SOG, BPSG, PSG, TEOS, FOX, TOSZ, HDP-CVD oxide, etc. The insulation layer may be formed on the substrate 500 by a CVD process, a PECVD process, a spin coating process, an ALD process, an HDP-CVD process, etc.

The insulation layer is removed until the substrate 500 is exposed such that isolation layers 505 are formed in the trenches. The isolation layers 505 may be obtained by a CMP process and/or an etch-back process. Some of the isolation layers 505 in the memory cell region IV may define active regions of the substrate 500 where memory cells of the semiconductor device are formed. One isolation layer located between the memory cell region IV and the dummy cell region III may have a width larger than those of other isolation layers 505 since one trench between the dummy cell region III and the memory cell region IV has the large width as described above.

A P-type well (not illustrated) may be formed in the substrate 500 by doping P-type impurities into the substrate 500 having the isolation layers 505. Alternatively, the P-type well may be formed in the substrate 500 before forming the isolation layers 505. Additionally, an N-type well may be formed in the dummy cell region III of the substrate 500 by implanting N-type impurities into the substrate 500 after forming the isolation layers 505 or before forming the isolation layers 505.

Second hard masks (not illustrated) are formed on the substrate 500 and the isolation layers 505. The second hard masks may expose the active regions of the substrate 500 defined by the isolation layers 505. The second hard masks may be formed using oxide, nitride and/or oxynitride. Each of the second hard masks may have a multi layer structure that includes an oxide layer, an organic layer and a nitride layer. The oxide layer may include silicon oxide obtained by a CVD process, and the organic layer may include amorphous carbon layer. The oxide layer may have a thickness of about 2,000 Å to about 3,000 Å, and the organic layer may also have a thickness of about 2,000 Å to about 3,000 Å. The nitride layer may include silicon nitride and may have a thickness of about 500 Å. The nitride layer may serve as an anti-reflective layer.

The exposed portions of the active regions are partially etched using the second hard masks as etching masks. Thus, recesses (not illustrated) are formed at the active regions. When the P-type well is formed in the memory cell region IV of the substrate 500, the recesses may be positioned in the P-type well.

A gate conductive layer (not illustrated) and a gate mask layer (not illustrated) are formed on the substrate 500 having the recesses. The gate conductive layer may be formed on the substrate 500 to fill up the recesses. The gate conductive layer may be formed using polysilicon, metal and/or metal compound and the gate mask layer may be formed using nitride or oxynitride. After the gate mask layer is etched to form gate masks (not illustrated) on the gate conductive layer, the gate conductive layer is patterned using the gate masks as etching masks. Therefore, gate structures (not illustrated) are formed at the active region of the substrate 500. Each of the gate structures includes a gate electrode and the gate mask. The gate electrodes may be partially buried in the substrate 500.

Impurities are implanted into portions of the memory cell region IV and the dummy cell region III between adjacent isolation layers 505, so that source/drain regions 515 and preliminary impurity regions 510 are simultaneously formed in the memory cell region IV and the dummy cell region III, respectively.

Referring to FIG. 11, a mask 520 is formed on the substrate 500 to cover the memory cell region IV, and then impurities may be doped into the preliminary impurity regions 510 in the dummy cell region III. Hence, impurity regions 525 are provided in the dummy cell region III. The impurities for forming the impurities regions 525 may include P-type impurities, for example, boron, boron fluoride, etc. The mask 520 may be formed using an organic material such as photoresist. In certain embodiments, processes for forming the source/drain regions 515 and the impurity regions 525 may be simplified since the source/drain regions 515 and the impurity regions 525 may be obtained using a single mask.

Referring to FIG. 12, an insulating interlayer 530 covering the gate structures is formed on the memory cell region IV and the dummy cell region III of the substrate 500. The insulating interlayer 530 may be formed using oxide by a CVD process, a PECVD process, a spin coating process, an ALD process, an HDP-CVD process, etc.

The insulating interlayer 530 is partially etched to form first contact holes (not illustrated) that expose the source/drain regions 515 in the memory cell region IV, and to form second contact holes (not illustrated) exposing the impurity regions 525 in the dummy cell region III. After a conductive layer (not illustrated) filling the first and the second contact holes is formed on the insulating interlayer 530 to the first and the second contact holes, the conductive layer is removed until the insulating interlayer 530 is exposed. Therefore, plugs 535 filling the first and the second contact holes are formed on the source/drain regions 515 and the impurity regions 525. The conductive layer may be formed using metal, doped polysilicon and/or metal compound.

Bit lines 540 and dummy bit line structures 541 are formed on the plugs 535. The bit lines 540 and the dummy bit line structures 541 may be formed by patterning a conductive layer after forming the conductive layer on the plugs 535 and the insulating interlayer 530. The bit lines 540 and the dummy bit line structures 541 may be formed using metal and/or metal compound. In certain embodiments, each of the bit lines 540 and the dummy bit line structures 541 may have a multi layer structure that includes at least one metal layer and at least one metal nitride layer.

Bit line spacers 550 and dummy bit line spacers 551 are formed on sidewalls of the bit lines 540 and the dummy bit line structures 541. The bit line and the dummy bit line spacers 550 and 551 may include nitride or oxynitride. The bit line and the dummy bit line spacers 550 and 551 may be formed by etching a nitride layer or an oxynitride layer covering the bit lines 540 and the dummy bit line structures 541.

An additional insulating interlayer (not illustrated) is formed on the insulating interlayer 530 to cover the bit lines 540 and the dummy bit line structures 541, capacitors (not illustrated) are formed on the additional insulating interlayer. The capacitors may be electrically connected to the source/drain regions 515 in the memory cell region IV. The dummy bit line structures 541 are electrically connected to a wiring 560 to receive negative voltage V_{BB} from (e.g.,) an external terminal. Thus, leakage current potentially generated in the peripheral area will not flow into the memory cell region IV, such that the cell transistors in the memory cell region IV are able to maintain required threshold voltages. Therefore, the semiconductor devices including the dummy bit line structures 541 provided improved electrical performance without refresh failures occurring in the cell transistors.

According to certain embodiments of the inventive concept, the dummy bit line structures 541 may be formed together with the bit lines 540 so that the semiconductor device enjoys a higher degree of integration without the additional wirings or terminals that characterize conventional solutions to the problem being address.

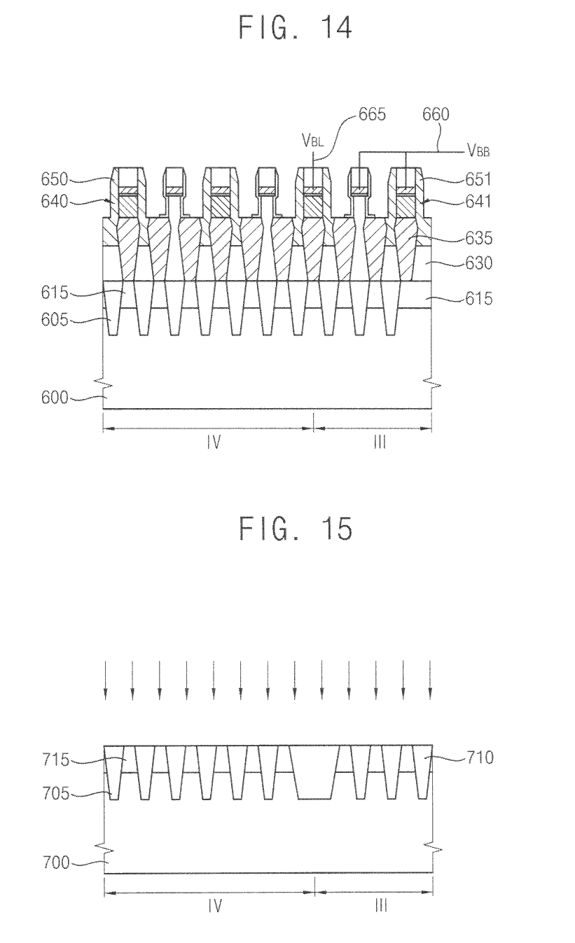

FIGS. 13 and 14 are cross sectional views further illustrating a method of manufacturing a semiconductor device having a dummy bit line structure in accordance with certain embodiments of the inventive concept.

Referring to FIG. 13, a semiconductor device is fabricated on a substrate 600 having a memory cell region IV and a dummy cell region III in a cell area. The substrate 600 further includes a peripheral circuit area (not illustrated). The substrate 600 may be formed from a semiconductor substrate, a substrate having a semiconductor layer, etc.

A pad oxide layer pattern (not illustrated) and a first hard mask are formed on the substrate 600. The pad oxide layer pattern may have a thin thickness of about 50 Å to 150 Å. The pad oxide layer pattern may include silicon oxide and the first hard mask may include nitride or oxynitride. The pad oxide layer pattern and the first hard mask layer may be obtained by patterning a pad oxide layer and a hard mask layer provided on the substrate 600.

The substrate 600 is partially etched using the first hard mask and the pad oxide layer pattern as etching masks to thereby form trenches (not illustrated) at an upper portion of the substrate 600. Here, one trench formed between the memory cell region IV and the dummy cell region III may have a greater width than the other trenches. An insulation layer (not illustrated) filling the trenches is formed on the substrate 600. The insulation layer may be formed using oxide by a CVD process, a PECVD process, a spin coating process, an ALD process, an HDP-CVD process, etc. Then, the insulation layer is removed by a CMP process and/or an etch-back process until the substrate 600 is exposed, and thus isolation layers 605 are formed in the trenches. The isolation layers 605 formed in the memory cell region IV may define active regions of the substrate 600 where memory cells of the semiconductor device are located. One of the isolation layers 605 formed between the memory cell region IV and the dummy cell region III may have a width substantially larger than those of other isolation layers 605.

A P-type well may be formed in the substrate 600 by doping P-type impurities into the substrate 600 after forming the isolation layers 605 or before forming the isolation layers 605. Further, liner layers including nitride may be formed on sidewalls of the trenches before forming the isolation layers 605. Additionally, an N-type well may be formed in the dummy cell region III of the substrate 600 by implanting N-type impurities into the substrate 500 after forming the isolation layers 605 or before forming the isolation layers 605.

Second hard masks (not illustrated) are formed on the isolation layers 405 and the substrate 600. The second hard masks may be formed using oxide, nitride and/or oxynitride. The second hard masks may have multi layer structures, respectively. For example, each of the second hard masks may have an oxide layer, an organic layer and a nitride layer. Here, the oxide layer may include silicon oxide obtained by a CVD process, and the organic layer may include amorphous carbon layer. The oxide layer may have a thickness of about 2,000 Å to about 3,000 Å, and the organic layer may also have a thickness of about 2,000 Å to about 3,000 Å. The nitride layer may include silicon nitride and may have a thickness of about 500 Å. The nitride layer may serve as an anti-reflective layer.

The active regions are partially etched using the second hard masks as etching masks. Hence, recesses (not illustrated) are formed at the active regions. When the P-type well is formed in the substrate 600, the recesses may be located in the P-type well. A gate conductive layer (not illustrated) and a gate mask layer (not illustrated) are formed on the substrate 600. The gate conductive layer may be formed on the substrate 600 to fill up the recesses. The gate conductive layer may be formed using polysilicon, metal and/or metal compound. The gate mask layer may be formed using nitride or oxynitride. After the gate mask layer is etched to form gate masks (not illustrated) on the gate conductive layer, the gate conductive layer is patterned using the gate masks as etching masks. Therefore, gate structures (not illustrated) are formed in the active region of the substrate 600. The gate structures include gate electrodes and gate masks, respectively. The gate electrodes may be partially buried in the substrate 600.

Impurities are doped into portions of the substrate 600 to form source/drain regions 615 and preliminary impurity regions 610. The source/drain regions 615 are positioned between adjacent gate structures in the memory cell region IV and the preliminary impurity regions 610 are located between the isolation layers 605 in the dummy cell region III.

Referring to FIG. 14, impurity regions 625 are formed in the dummy cell region III using a process substantially the same (or substantially similar to) the process described above with reference to FIG. 11. The impurity regions 625 may be formed by implanting P-type impurities such as boron, boron fluoride.

An insulating interlayer 630 is formed on the substrate 600 to cover the gate structures. The insulating interlayer 630 may be formed using oxide by a CVD process, a PECVD process, a spin coating process, an ALD process, an HDP-CVD process, etc. The insulating interlayer 630 is partially etched to form first contact holes (not illustrated) that expose the source/drain regions 615 in the memory cell region IV. Simultaneously, second contact holes (not illustrated) are formed through the insulating interlayer 630 in the dummy cell region III. The second contact holes expose the impurity regions 625 in the dummy cell region III.

A conductive layer (not illustrated) filling the first and the second contact holes is formed on the insulating interlayer 630, and then the conductive layer is removed until the insulating interlayer 630 is exposed. Therefore, plugs 635 filling the first and the second contact holes are formed on the source/drain regions 615 and the impurity regions 625. The plugs 635 may include metal, doped polysilicon and/or metal compound.

Bit lines 640 and dummy bit line structures 641 are formed on the plugs 635. The bit lines 640 and the dummy bit line structures 641 may be formed by patterning an additional conductive layer (not illustrated) after forming the additional conductive layer on the plugs 635 and the insulating interlayer 630. The bit lines 640 and the dummy bit line structures 641 may include metal and/or metal compound. In certain embodiments, the bit lines 640 and the dummy bit line structures 641 may have multi layer structures, respectively.

Bit line spacers 650 and dummy bit line spacers 651 are respectively formed on sidewalls of the bit lines 640 and the dummy bit line structures 641. The bit line spacers 650 and the dummy bit line spacers 651 may be formed using nitride or oxynitride.

After an additional insulating interlayer (not illustrated) covering the bit lines 640 and the dummy bit line structures 641 is formed on the insulating interlayer 630, capacitors (not illustrated) are formed on the additional insulating interlayer. Here, the capacitors may be electrically connected to the source/drain regions 615 in the memory cell region IV. The dummy bit line structures 641 are electrically connected to a wiring 660 such that the negative voltage V_{BB} may be applied to the dummy bit line structures 641 to prevent leakage current potentially generated in the peripheral area from flowing into the memory cell region IV. Therefore, cell transistors in the memory cell region IV may maintain desired threshold voltages to prevent refresh failures of the cell transistors, and thus the semiconductor devices including the dummy bit line structures 641 may exhibit improved electrical performance.

In certain embodiments of the inventive concept, the dummy bit line structure positioned adjacent to the memory cell region IV may receive a positive voltage similar to that of the cell transistors in the memory cell region IV when the source/drain regions 615 are formed without an implantation mask. Namely, the dummy bit line structure near the memory cell region IV may work unstably because the source/drain regions 615 are directly formed in the memory cell region IV without an implantation mask. Therefore, a positive voltage may be applied to the dummy bit line structure adjacent to the memory cell region IV to stabilize the operation of the outermost dummy bit line structure. As a result, the semiconductor device may effectively provide improved operating characteristics without refresh failures occurring in the memory cells.

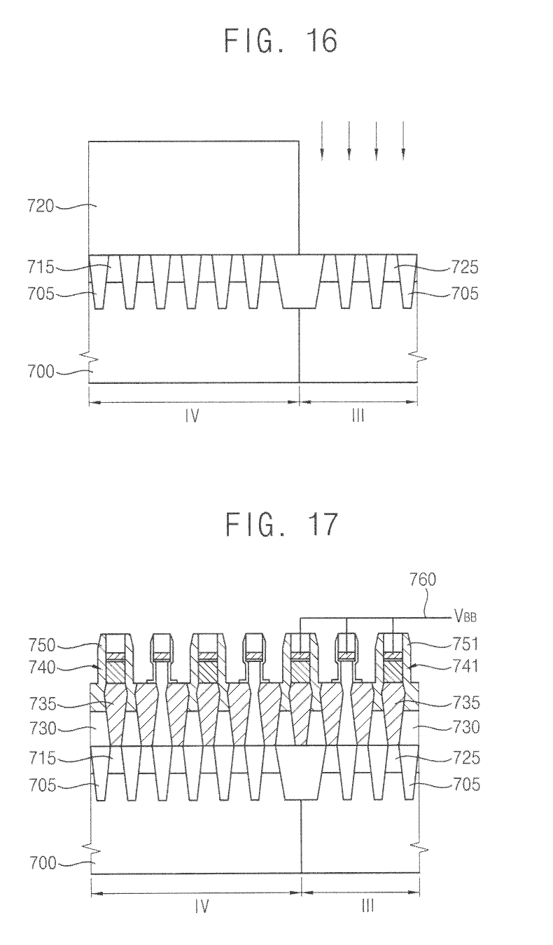

FIGS. 15, 16 and 17 are cross sectional views illustrating a method of manufacturing a semiconductor device having a dummy bit line structure in accordance with certain embodiments of the inventive concept.

Referring to FIG. 15, a semiconductor device is fabricated on a substrate 700 having a cell area and a peripheral circuit area. The cell area includes a memory cell region IV and a dummy cell region III. A pad oxide layer pattern (not illustrated) and a first hard mask (not illustrated) are formed on the substrate 700. The pad oxide layer pattern may have a relatively thin thickness of about 50 Å to about 150 Å. The first hard mask may include nitride, oxynitride, etc. The substrate 700 is partially etched using the first hard mask and the pad oxide layer pattern as etching masks to form trenches (not illustrated) at an upper portion of the substrate 700. One of the trenches formed between the memory cell region IV and the dummy cell region III may have a greater width than the other trenches.

An insulation layer (not illustrated) filling the trenches is formed on the substrate 700. The insulation layer may be formed using oxide by a CVD process, a PECVD process, a spin coating process, an ALD process, an HDP-CVD process, etc. The insulation layer is removed until the substrate 700 is exposed. Thus, isolation layers 705 are formed in the trenches. The isolation layers 705 in the memory cell region IV may define active regions of the substrate 700 where memory cells of the semiconductor device are formed. One of the isolation layers 705 formed between the memory cell region IV and the dummy cell region III may have a width larger than those of other isolation layers 705. A P-type well (not illustrated) may be formed in the substrate 700 by doping P-type impurities into the substrate 700 after forming the isolation layers 705 or before forming the isolation layers 705. Further, an N-type well may be formed in the dummy cell region III of the substrate 700 by implanting N-type impurities into the dummy cell region III of the substrate 700 after forming the isolation layers 705 or before forming the isolation layers 705.

Second hard masks (not illustrated) exposing the active regions are formed on the substrate 500 and the isolation layers 705. In some embodiments, the second hard masks may have multi layer structures that include oxide layers, organic layers and nitride layers. The oxide layers may include silicon oxide obtained by a CVD process, and the organic layers may include amorphous carbon layer. Each of the oxide layers may have a thickness of about 2,000 Å to 3,000 Å, and may also have a thickness of about 2,000 Å to about 3,000 Å. Each of the nitride layers may include silicon nitride and may have a thickness of about 500 Å. The nitride layers may serve as anti-reflective layers.

The exposed portions of the active regions are partially etched using the second hard masks as etching masks, so that recesses (not illustrated) are formed in the active regions. A gate conductive layer (not illustrated) and a gate mask layer (not illustrated) are formed on the substrate 700 having the recesses. The gate conductive layer may be formed on the substrate 700 to fill up the recesses. The gate conductive layer may be formed using polysilicon, metal and/or metal compound and the gate mask layer may be formed using nitride or oxynitride. After the gate mask layer is etched to form gate masks (not illustrated) on the gate conductive layer, the gate conductive layer is patterned using the gate masks as etching masks. Thus, gate structures (not illustrated) are formed at the active region of the substrate 700. The gate structures include gate electrodes and gate masks, respectively. Here, the gate electrodes may be partially buried in the substrate 700.

Impurities are implanted into portions of the memory cell region IV and the dummy cell region III between adjacent isolation layers 705, so that source/drain regions 715 and preliminary impurity regions 710 are formed in the memory cell region IV and the dummy cell region III, respectively. Namely, the source/drain regions 715 and the preliminary impurity regions 710 are simultaneously obtained.

Referring to FIG. 16, after a mask 720 covering the memory cell region IV is formed on the substrate 700, impurities may be doped into the preliminary impurity regions 710 in the dummy cell region III. Thus, impurity regions 725 are formed in the dummy cell region III. The impurities for the impurities regions 725 may include P-type impurities. Therefore, processes for forming the source/drain regions 715 and the impurity regions 725 may be simplified because the source/drain regions 715 and the impurity regions 725 may be obtained using a single mask.

Referring to FIG. 17, an insulating interlayer 730 covering the gate structures is formed on the memory cell region IV and the dummy cell region III of the substrate 700. The insulating interlayer 730 may be formed using oxide by a CVD process, a PECVD process, a spin coating process, an ALD process, an HDP-CVD process, etc. The insulating interlayer 730 is partially etched to form first contact holes (not illustrated) exposing the source/drain regions 715 in the memory cell region IV, and to form second contact holes (not illustrated) exposing the impurity regions 725 in the dummy cell region III. After a conductive layer (not illustrated) filling the first and the second contact holes is formed on the insulating interlayer 730 to the first and the second contact holes, the conductive layer is removed until the insulating interlayer 730 is exposed. Hence, plugs 735 filling the first and the second contact holes are formed on the source/drain regions 715 and the impurity regions 725. The conductive layer may be formed using metal, doped polysilicon and/or metal compound.

Bit lines 740 and dummy bit line structures 741 are formed on the plugs 735 and the insulating interlayer 730. The bit lines 740 and the dummy bit line structures 741 may include metal and/or metal compound. The bit lines 740 and the dummy bit line structures 741 may respectively have multi layer structures that include at least one metal layer and at least one metal nitride layer. Bit line spacers 750 and dummy bit line spacers 751 are formed on sidewalls of the bit lines 740 and the dummy bit line structures 741. The bit line and the dummy bit line spacers 750 and 751 may include nitride or oxynitride.

An additional insulating interlayer (not illustrated) covering the bit lines 740 and the dummy bit line structures 741 is formed on the insulating interlayer 730, capacitors (not illustrated) are formed on the additional insulating interlayer. The capacitors may be electrically connected to the source/drain regions 715 in the memory cell region IV. The dummy bit line structures 741 are electrically connected to a wiring 760 to receive negative voltages (V_{BB}) from an external terminal through the wiring 760. A leakage current potentially generated in the peripheral area may not flow into the memory cell region IV because of the dummy bit line structures 741, such that the cell transistors in the memory cell region IV may be able to maintain required threshold voltages. As a result, the semiconductor devices including the dummy bit line structures 741 may exhibit improved electrical performance without refresh failures occurring in the cell transistors. Further, the dummy bit line structures 741 may be formed together with the bit lines 740. Thus the semiconductor device may enjoy a higher degree of integration density without the requirement of forming additional wirings or terminals that characterize conventional solutions to the problem being address, considering (e.g.,) the well bias in the memory cell region IV.

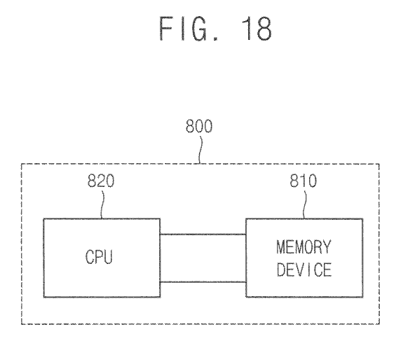

FIG. 18 is a general block diagram illustrating a memory system capable of incorporating a semiconductor memory device according to an embodiment of the inventive concept.

Referring to FIG. 18, a memory system 800 comprises a memory device 810 and a central processing unit (CPU) 820. The memory device 810 is electrically connected to the CPU 820. For example, the memory system 800 may include a personal computer, a personal data assistant, etc. The memory device 810 may be directly connected to the CPU 820 or may be electrically connected to the CPU 820 through a BUS.

The memory device 810 may include a DRAM device having dummy bit line structures manufactured through the above-described processes. Alternatively, the memory device 810 may include other semiconductor devices, for example, SRAM devices, flash memory devices, etc.

According to certain embodiments of the inventive concept including those illustrated herein, a semiconductor device comprises a dummy bit line structure preventing leakage current potentially generated within a peripheral circuit area from flowing into a cell area. Thus, refresh failures for memory cells in the semiconductor device may be effectively prevented. Nevertheless, a very high degree of integration density may be provided at reduced fabrication cost and complexity, because the dummy bit line structure may be fabricated in substantially the same as (or substantially similar to) a bit line in the semiconductor memory device.

The foregoing is illustrative of the inventive concept and is not to be construed as limiting thereof. Although certain embodiments have been described, those skilled in the art will readily appreciate that many modifications are possible in the embodiments without materially departing from the novel teachings and advantages associated with the inventive concept. Accordingly, all such modifications are intended to be included within the scope of the inventive concept as defined in the claims. Therefore, it is to be understood that the foregoing is illustrative of the inventive concept and is not to be construed as limited to only the specific embodiments disclosed, and that modifications to the disclosed embodiments, as well as other embodiments, are intended to be included within the scope of the appended claims. The inventive concept is defined by the following claims, with equivalents of the claims to be included therein.

1. A semiconductor device, comprising:
a substrate having a cell area including a memory cell region and a dummy cell region;
gate structures formed in the cell region;
an insulating interlayer formed on the substrate to cover the gate structures;
plugs formed through the insulating interlayer;
bit lines contacting the plugs in the memory cell region; and
dummy bit line structures contacting the plugs in the dummy cell region.

2. The semiconductor device of claim 1, further comprising:
isolation layers formed on the substrate;
source/drain regions formed between the gate structures in the memory cell region; and
impurity regions formed between the isolation layers in the dummy cell region.

3. The semiconductor device of claim 2, wherein one of the isolation layers formed between the memory cell region and the dummy cell region has a greater width than other isolation layers.

4. The semiconductor device of claim 2, wherein the impurity regions include P-type impurities.

5. The semiconductor device of claim 4, further comprising:
a P-type well formed in the memory cell region: and
an N-type well formed in the dummy cell region.

6. The semiconductor device of claim 2, further comprising:
a wiring electrically connected to the dummy bit line structures for applying negative voltages to the dummy bit line structures to prevent a leakage current potentially generated in a peripheral circuit area from flowing into the cell area.

7. The semiconductor device of claim 6, wherein the dummy bit line structures are electrically connected to the impurity regions.

8. The semiconductor device of claim 6, wherein a positive voltage is applied to at least one of the dummy bit line structure adjacent to the memory cell region.

9. The semiconductor device of claim 1, further comprising:
dummy bit line spacers respectively formed on sidewalls of the dummy bit line structures.

10. The semiconductor device of claim 1, wherein the dummy bit line structures have substantially the same structures as the bit lines.

11. The semiconductor device of claim 8, wherein each of the dummy bit line structures comprises a dummy bit line and a dummy bit line mask.

12. The semiconductor device of claim 9, wherein the dummy bit line comprises at least one of doped polysilicon, metal, and metal compound, and the dummy bit line mask comprises nitride or oxynitride.

13-20. (canceled)
